(19) United States
(12) Patent Application Publication
(10) Pub. No.: US 2006/0088999 A1
(43) Pub. Date: Apr. 27, 2006

(54) Methods and compositions for chemical mechanical polishing substrates

(75) Inventors: Garrett H. Sin, San Jose, CA (US); Winston Y. Su, Cupertino, CA (US); Sidney P. Huey, Fremont, CA (US)

Correspondence Address: PATTERSON & SHERIDAN, LLP, 3040 POST OAK BOULEVARD, SUITE 1500, HOUSTON, TX, 77056, US

(73) Assignee: APPLIED MATERIALS, INC.

(21) Appl. No.: 11/274,378

(22) Filed: Nov. 14, 2005

Related U.S. Application Data
(63) Continuation of application No. 10/971,561, filed on Oct. 22, 2004.

(51) Int. Cl. H01L 21/302

(52) U.S. Cl. 438/689

(57) ABSTRACT

Methods and compositions are provided for planarizing a substrate surface with reduced or minimal defects in surface topography. In one aspect, a method is provided for processing a substrate comprising a dielectric material and polysilicon material disposed thereon, polishing the polysilicon material with a high topography selective polishing composition, and polishing the polysilicon material with a material selective composition.

### CROSS-REFERENCE TO RELATED APPLICATIONS

This application is a continuation of co-pending U.S. patent application Ser. No. 10/971,561, filed Oct. 22, 2004, which is herein incorporated by reference.

### BACKGROUND OF THE INVENTION

1. Field of the Invention

The invention relates generally to the fabrication of semiconductor devices and to polishing and planarizing of substrates.

2. Description of the Related Art

Reliably producing sub-half micron and smaller features is one of the key technologies for the next generation of very large-scale integration (VLSI) and ultra large-scale integration (ULSI) of semiconductor devices. However, the shrinking dimensions of interconnects in VLSI and ULSI technology has placed additional demands on the processing capabilities. The multilevel interconnects that lie at the heart of this technology require precise processing of high aspect ratio features, such as vias, contacts, lines, and other interconnects. Reliable formation of these interconnects is important to VLSI and ULSI success and to the continued effort to increase circuit density and quality of individual substrates and die.

Multilevel interconnects are formed by the sequential deposition and removal of materials from the substrate surface to form features therein. As layers of materials are sequentially deposited and removed, the uppermost surface of the substrate may become non-planar across its surface and require planarization prior to further processing. Planarizing a surface, or “polishing” a surface, is a process where material is removed from the surface of the substrate to form a generally

Chemical mechanical planarization, or chemical mechanical polishing (CMP), is a common technique used to planarize substrates. In conventional CMP techniques, a substrate carrier or polishing head is mounted on a carrier assembly and positioned in contact with a polishing article in a CMP apparatus. The carrier assembly provides a controllable pressure to the substrate urging the substrate against the polishing article. The substrate and polishing article are moved in a relative motion to one another.

A polishing composition is provided to the polishing article to effect chemical activity in removing material from the substrate surface. The polishing composition may contain abrasive material to enhance the mechanical activity between the substrate and polishing article. Thus, the CMP apparatus effects polishing or rubbing movement between the surface of the substrate and the polishing article while dispersing a polishing composition to effect both chemical activity and mechanical activity. The chemical and mechanical activity removes excess deposited materials as well as planarizing a substrate surface.

Chemical mechanical polishing may be used in the fabrication of polysilicon structures. Polysilicon structures that may be used to form components of a transistor, such as source/drain junctions or channel stops, on a substrate surface during fabrication. An example of a polysilicon structure includes depositing an oxide material layer on a substrate material, patterning and etching the oxide material layer to form a feature definition, depositing a polysilicon fill of the feature definitions, and polishing the substrate surface to remove excess polysilicon to form a feature.

Polysilicon material is typically polished using a conventional polishing article and an abrasive containing polishing composition. However, polishing polysilicon material with typical polishing processes has been observed to result in overpolishing of the substrate surface and result in the formation of recesses in the polysilicon filled features and other topographical defects. This phenomenon of overpolishing and forming recesses in the polysilicon filled features is referred to as dishing. Dishing is highly undesirable because dishing of substrate features may detrimentally affect subsequent device fabrication.

FIGS. 1A-1C are schematic diagrams illustrating the phenomena of dishing and erosion, another type of topographical defect. FIG. 1A shows an example of one stage of the polysilicon device formation process with an oxide layer 20 disposed and patterned on a substrate 10. A polysilicon material 30 is deposited on the substrate surface in a sufficient amount to fill feature definitions 35.

FIG. 1B illustrates the phenomena of dishing observed with polishing by conventional techniques. During polishing of the polysilicon material 30 to the oxide layer 20, the polysilicon material 30 may be overpolished and surface defects, such as recesses 40, may be formed in the polysilicon material 30. The excess amount of polysilicon material removed from overpolishing the substrate surface, represented by dashed lines, is considered the amount of dishing 50 of the feature.

FIG. 1C illustrates another type of typographical defect referred to as erosion. Erosion results in excess removal 60 of the oxide material 20 surrounding around the deposited polysilicon material 30. Dishing and erosion result in a non-planar surface that impairs the ability to print high-resolution lines during subsequent photolithographic steps and detrimentally affects subsequent surface topography of the substrate and device formation.

Therefore, there exists a need for a method and polishing composition that facilitates the removal of dielectric materials with minimal or reduced defect formation during polishing of a substrate surface.

### SUMMARY OF THE INVENTION

Aspects of the invention generally provide a method and composition for planarizing a substrate surface with reduced or minimal defects in surface topography and reduced processing times. In one aspect, a method is provided for processing a substrate including positioning the substrate in a polishing apparatus having one or more platens and polishing articles disposed on the one or more platens, and the substrate comprising a dielectric material and polysilicon material disposed thereon, polishing the polysilicon material with a high topography selective polishing composition, and polishing the polysilicon material with a material selective composition.

In another aspect, a method is provided for processing a substrate including positioning a substrate comprising a polysilicon material disposed on a dielectric material in a polishing apparatus having one or more platens and polishing articles disposed on the one or more platens, and the polysilicon material comprises a non-planar surface topography having high topographical features and low topographical features, planarizing the polysilicon material with a ceria based composition, wherein the ceria based composition removes high topographical features at a greater removal rate than low topographical features, and polishing the polysilicon material with a silica based composition, wherein the silica based composition removes polysilicon material at a higher removal rate than the dielectric material.

In another aspect, a method for processing a substrate is provided including positioning the substrate in a polishing apparatus having one or more platens and polishing articles disposed on the one or more platens, and the substrate comprising an oxide based material and polysilicon material having a non-planar surface topography disposed thereon, polishing the substrate to remove a first portion of the polysilicon non-planar surface topography with a first high topography selective composition, polishing the substrate to remove a second portion of the polysilicon non-planar surface topography with a second high topography selective composition, and polishing the polysilicon material with a silica based composition to expose the oxide based material.

### BRIEF DESCRIPTION OF THE DRAWINGS

So that the manner in which the above recited aspects of the invention are attained and can be understood in detail, a more particular description of the invention, briefly summarized above, may be had by reference to the embodiments thereof which are illustrated in the appended drawings.

It is to be noted, however, that the appended drawings illustrate only typical embodiments of this invention and are therefore not to be considered limiting of its scope, for the invention may admit to other equally effective embodiments.

FIGS. 1A-1C are schematic diagrams illustrating the phenomena of dishing and erosion; and

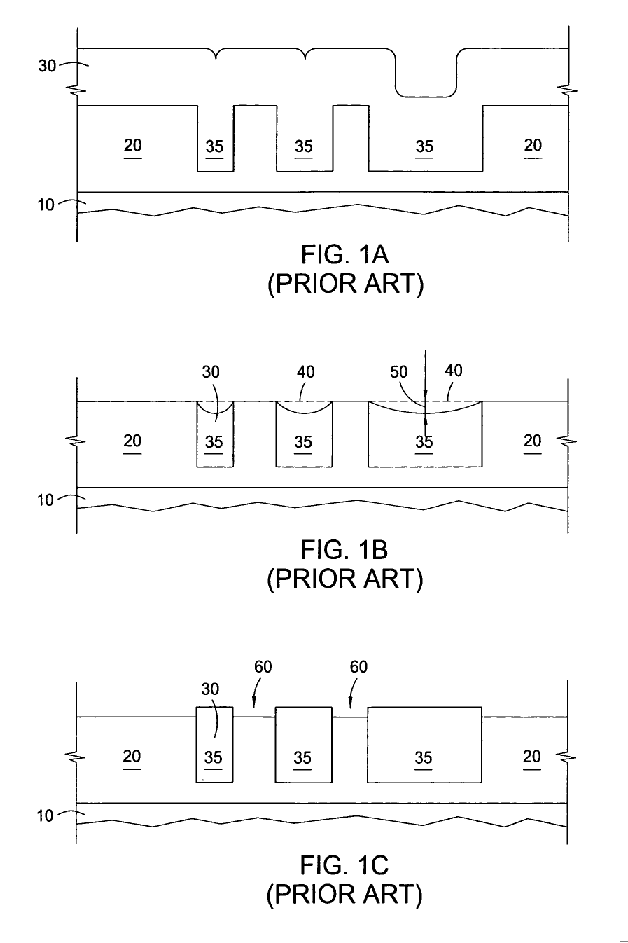

FIGS. 2A-2D are schematic diagrams illustrating polishing a substrate by one embodiment of the process herein.

### DETAILED DESCRIPTION OF THE PREFERRED EMBODIMENT

In general, aspects of the invention provide compositions and methods for planarizing a substrate surface with reduced or minimal defects in surface topography. The invention will be described below in reference to a planarizing process for the removal of polysilicon materials from a substrate surface by chemical mechanical planarization, or chemical mechanical polishing (CMP) technique. Chemical mechanical polishing is broadly defined herein as polishing a substrate by a combination of chemical and mechanical activity.

The planarizing process and composition as described herein used to polish a substrate may be performed in chemical mechanical polishing process equipment, such as the Mirra® polishing system, the Mirra® Mesa™ polishing system, the Reflexion LK™ polishing system, and the Reflexion™ polishing system, all of which are available from Applied Materials, Inc. The Mirra® polishing system is further described in U.S. Pat. No. 5,738,574, entitled, “Continuous Processing System for Chemical Mechanical Polishing,” the entirety of which is incorporated herein by reference to the extent not inconsistent with the invention.

Although, the processes and compositions described herein are illustrated utilizing a three platen system, such as the Mirra® polishing system, any system enabling chemical mechanical polishing using the composition or processes described herein can be used to advantage. Examples of other suitable apparatus include orbital polishing systems, such as the Obsidian 8200C System available from Applied Materials, Inc., or a linear polishing system, using a sliding or circulating polishing belt or similar device. An example of a linear polishing system is more fully described in co-pending U.S. patent Ser. No. 6,244,935, issued on Jun. 12, 2001, and incorporated herein by reference to the extent not inconsistent with the invention.

Chemical Mechanical Polishing Process

Aspects of the invention provide polishing methods and compositions to planarize a substrate surface with reduced or minimal topographical defect formation during a polishing process for polysilicon materials. Generally, a method is provided for processing a substrate including positioning a substrate comprising at least a dielectric material and a polysilicon material, which is considered a conductive material, disposed thereon, polishing the polysilicon material with a high topography selective polishing composition, and polishing the polysilicon material with a material selective composition.

A material selectivity is broadly defined herein as the preferential removal of one material in comparison to another material, and typically denoted as a removal rate ratio between a first material and second, or subsequent, materials. A high topography selectivity is broadly defined herein as preferential removal of higher topographical features, such as peaks, compared to lower topographical features, such as valleys. Bulk material is broadly described herein as material deposited on the substrate in an amount more than sufficient to substantially fill features formed on the substrate surface.

Residual dielectric material is broadly defined as any bulk material remaining after one or more polishing process steps and may further include any additional materials from layers disposed below the bulk material. Residual material may partially or completely cover the surface a substrate. For example, residual material may cover the entire substrate surface or may partially cover the substrate surface, such as about 25% or less of the surface area of the substrate.

The polysilicon polishing process includes a topography planarization step followed by a processing step to remove the remaining polysilicon material disposed above a feature defined in a dielectric material. The process may be performed on one or more platens. In a two platen polishing process, a polishing method may include positioning a substrate comprising at least a dielectric material and polysilicon material disposed thereon in a polishing apparatus, polishing the substrate with a high topography selective polishing composition and polishing the substrate with a material selective polishing composition.

In one embodiment of the polysilicon polishing process, the topography planarization step may be performed on one or two platens, with a first and a second portion of the topography material being removed on first and second platens respectively, and the remaining polysilicon material removed on a third platen. A three platen polishing process includes polishing the substrate surface to remove a first portion of the polysilicon layer on the first platen with a first high topography selective polishing composition, polishing the substrate surface to remove a second portion of the polysilicon layer on the second platen with a second high topography selective polishing composition, and a polishing residual polysilicon material with a material selective polishing composition substrate on a third platen. The same high topography selective polishing composition may be used for the first and second polishing steps on a three platen polishing process. An illustration of a three platen polishing process is as follows.

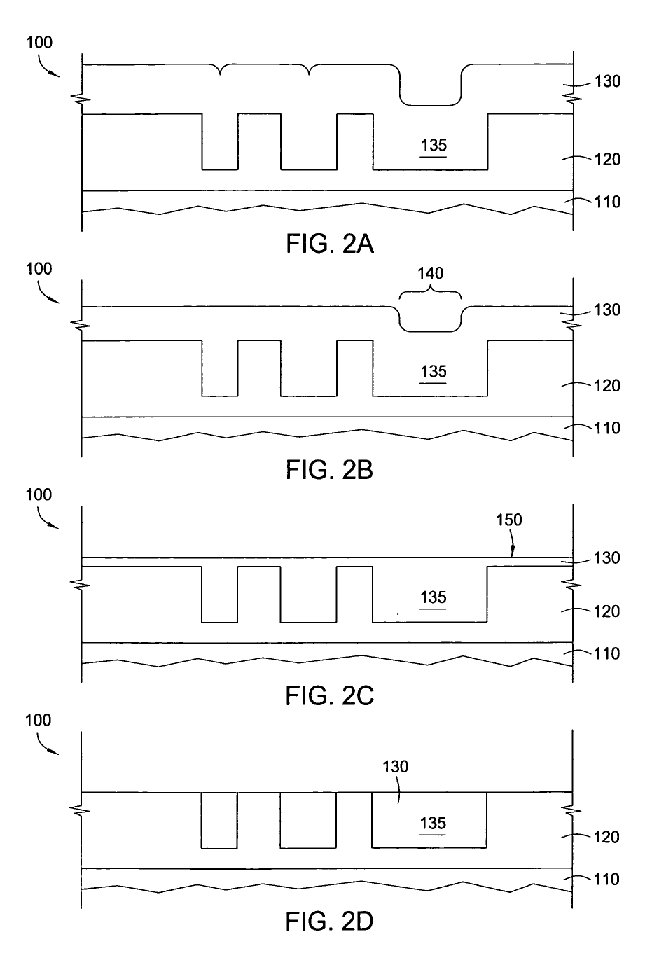

FIGS. 2A-2D illustrate one embodiment of polishing a substrate by one embodiment of the process herein. Referring to FIG. 2A, the substrate 100 comprises a substrate material 110, such as silicon, a patterned dielectric material 120 disposed on the substrate material, and a bulk polysilicon material 130 disposed thereon to fill feature definitions 135 formed in the dielectric material 120.

The dielectric material may include silicon dioxide, silicon nitride, phosphorus-doped silicon glass (PSG), boron-phosphorus-doped silicon glass (BPSG), and silicon dioxide derived from tetraethyl orthosilicate (TEOS), high density plasma chemical vapor deposition (HDP-CVD) silicon oxides (HDP oxides), silane by plasma enhanced chemical vapor deposition (PECVD) can be employed, and combinations thereof, of which silicon oxide is preferred. The polysilicon may further be doped to enhance or modify electrical properties. Dopants include, for example, boron and phosphorus.

The polysilicon material may be deposited to a thickness between about 1000 Å and about 10,000 Å, such as between about 1000 Å and about 6000 Å, for example, about 2000 Å, on the oxide layer, which has a thickness between about 500 Å and about 3000 Å, such as about 90 Å, 120 Å, or 2800 Å. The deposited polysilicon material. For example, may have topography features with a difference in height between the peaks and valleys of about 500 Å to about 5,000 Å.

The substrate is polished with a first high topography selective polishing composition on a first platen to remove a portion of the bulk polysilicon material having topography formed therein. High topography selective compositions may include ceria-based abrasive compositions that remove high topography features at higher rates than low topography features. High topography selective polishing compositions may be formed by having additives combined or mixed with abrasive solutions, such as ceria abrasive solution. The additives typically comprise compounds that help control the removal rate of high and low topographical features. An example of a suitable abrasive solution is a ceria based composition of CES330-10 (Tradename), commercially available from Seimi Chemical Company (aka Asahi), of Japan, and an example of a suitable additive solution is ADD103-10, commercially available from Seimi Chemical Company (aka Asahi), of Japan. Other examples of commercially available compositions include the Microplanar™ series of slurries from EKC Technology of Hayward Calif., and the HS-8000 (Tradename) series of compositions, for example, abrasive slurries include HS-8005-C7, -D6, -D4, and -D7 and additives including HS-8102 GP-2 and HS-8103 GPE, all from Hitachi Chemical Company of Japan.

The ratio of abrasive solutions to additive solution is generally between about 1:1 and about 3:1. An additional solvent may be used in the composition. The solvent may be any suitable solvent for a polishing composition, of which water, such as deionized water, is preferred. The solvent, such as deionized water (DI water or DIW), may be used to dilute the abrasive and additive solutions. For example, deionized water may be used to dilute the abrasive solution and additive solution to form a polishing composition having an abrasive solution to additive solution to deionized water of about 1:1:8, or as a percentage, 10% abrasive solution, 10% additive solution, and 80% deionized water. The composition may comprise a ratio of 1 part CES330-10 solution as the abrasive solution, 1 part ADD103-10 solution as the additive solution, and, 8 parts deionized water.

The abrasive solutions and the additive solution may themselves include a solvent prior to being mixed together, with or without the additional solvent. For example, the abrasive solutions or additive solutions may comprises 10% (volume percent or weight percent) abrasive or additive and 90% deionized water, a ratio of 1:9 abrasives or additives to solvent. When the solutions already including a solvent are diluted in the additional solvent, the diluted composition may have reduced amount of abrasive and additives content. For example if the abrasive solution and the additive solution having 10% (volume percent or weight percent) abrasive or additive and 90% (volume percent or weight percent) deionized water, respectively, are diluted at a ratio of abrasive solution to additive solution to deionized water of about 1:1:8, the final composition may include 1% abrasives (volume percent or weight percent), 1% additives (volume percent or weight percent), and the remainder solvent, such as deionized water.

The first high topography selective polishing step includes positioning the substrate in a carrier head for processing, providing the substrate to a first platen having a polishing article disposed therein, providing the high topography selective polishing composition to the platen, providing relative motion between the substrate and polishing article, and contacting the substrate and polishing article.

The high topography selective polishing composition is provided to the platen at a flow rate of between about 50 milliliters per minute (ml/min) and about 500 ml/min, such as between about 100 milliliters per minute (ml/min) and about 300 ml/min, for example, about 200 ml/min. Relative motion is provided between the substrate and the polishing article by providing a carrier head rotational rate and platen rotational rate between about 20 RPM and about 200 RPM, such as between about 50 RPM and about 120 RPM, for example 87 RPM for the carrier head rotational speed and about 93 RPM for platen rotational speed. The substrate and polishing pad are contacted at a contact pressure between 1 psi and about 10 psi, such as between about 2 psi and about 6 psi, for example between about 3 psi and about 5 psi. The polishing process is performed for between about 30 and about 240 seconds, such as about 150 seconds. Processing parameters such as rotational speed, duration, and polishing pressure, will vary based upon the substrate material, material layer thicknesses, and compositions used and operator requirements. For example, if the high topography selective polishing step is performed on a single platen, the polishing time may be extended in order to remove the desired amount of material.

An example of the first high topography selective polishing step includes supplying a composition of 1 part CES330-10 solution as the additive solution, 1 part ADD103-10 solution as the additive solution, and, 8 parts deionized water. The CES330-10 solution and the 1 part ADD103-10 solution have a 10% abrasive or additive to 90% deionized water composition, respectively, resulting in a composition having 1% abrasive (volume percent or weight percent), 1% additives (volume percent or weight percent), and the remainder deionized water. The composition is delivered with a composition delivery rate of about 200 ml/min and then the polysilicon material is removed from the substrate surface by polishing the substrate at a polishing pressure of about 3 psi with a platen rotational speed of about 93 rpm and a carrier head rotational speed of about 87 rpm for approximately 150 seconds.

FIG. 2B is a cross-sectional of the substrate after the first high topography selective polishing step. FIG. 2B indicate that there still exists topographical features 40 that prevent the formation of a planar surface. The second processing step is used to remove the remaining topographical features 40 from the polysilicon material 30 using a second high topography selective polishing step. The same high topography selective polishing composition as used in the first high topography selective polishing step may be used in the second high topography selective polishing step. An example of a suitable second high topography selective composition is a ceria based composition of CES330-10 (Tradename), commercially available from Seimi Chemical Company (aka Asahi), of Japan, and an example of a suitable additive solution is ADD103-10, commercially available from Seimi Chemical Company (aka Asahi), of Japan.

The second high topography selective polishing step includes positioning the substrate in a carrier head for processing, providing the substrate to a second platen having a polishing article disposed therein, providing the second high topography selective polishing composition to the platen, providing relative motion between the substrate and polishing article, and contacting the substrate and polishing article.

The second high topography selective polishing composition is provided to the platen at a flow rate of between about 50 milliliters per minute (ml/min) and about 500 ml/min, such as between about 100 milliliters per minute (ml/min) and about 300 ml/min, for example, about 200 ml/min. Relative motion is provided between the substrate and the polishing article by providing a carrier head rotational rate and platen rotational rate between about 20 RPM and about 200 RPM, such as between about 50 RPM and about 120 RPM, for example 87 RPM for the carrier head rotational speed and about 93 RPM for platen rotational speed. The substrate and polishing pad are contacted at contact pressure between 1 psi and about 10 psi, such as between about 2 psi and about 6 psi, for example between about 3 psi and about 5 psi. The polishing process is performed for between about 30 and about 240 seconds, such as about 150 seconds. Processing parameters such as rotational speed, duration, and polishing pressure, will vary based upon the substrate material, material layer thicknesses, and compositions used and operator requirements.

An example of the second high topography selective polishing step includes supplying a composition of 1 part CES330-10 solution as the additive solution, 1 part ADD103-10 solution as the additive solution, and, 8 parts deionized water. The CES330-10 solution and the 1 part ADD103-10 solution have a 10% abrasive or additive to 90% deionized water composition, respectively, resulting in a composition having 1% abrasive (volume percent or weight percent), 1% additives (volume percent or weight percent), and the remainder deionized water, at a delivery rate of about 200 ml/min and then removing bulk polysilicon material from the substrate surface by polishing the substrate at a polishing pressure of about 3 psi with a platen rotational speed of about 93 RPM and a carrier head rotational speed of about 87 RPM for approximately 150 seconds.

Referring to FIG. 2C, a residual polysilicon material 150 is removed by polishing the polysilicon material with a material selective polishing composition. The material selective compositions may have a selectivity, or removal rate ratio, of polysilicon to silicon oxide greater than 1:1. In one embodiment, the material selective composition may have a selectivity, or removal rate ratio, of polysilicon to silicon oxide between greater than 1:1 and less than or equal to about 1000:1, such as between about 100:1 and about 600:1, for example, about 600:1. Generally, the material selective composition is a silica based composition that provide for effective polysilicon residual removal with minimal erosion of the surrounding oxide material.

The material selective composition includes between about 10 weight percent (wt. %) and about 30 wt. % of an abrasive solution. The abrasive solutions may contain between about 10 weight percent (wt. %) and about 30 wt. % of silica abrasive particles. Examples of the material selective abrasive solutions includes the Planerlite (Tradename) series of slurries, such as Planerlite 6107 (Tradename) and DCM-P4 (Tradename), commercially available from Fujimi of Japan, and Klebosol 1509-12 slurry, from Rodel Inc., of Phoenix, Ariz.

An additional solvent may be used in the material selective composition. The solvent may be any suitable solvent for a polishing composition, of which water, such as deionized water, is preferred. The solvent, such as deionized water (DI water or DIW), may be used to dilute the abrasive solution, for example, deionized water may be used to dilute the abrasive solution s and additives to form a polishing composition having an abrasive solution to deionized water of about 1:9, or as a percentage, 10% abrasive solution and 90% deionized water. The composition may comprise a ratio of 1 part DCM-P4 or Planerlite 6107 solution as the abrasive solution and 9 parts deionized water. The abrasive solutions may themselves include a solvent prior to being mixed together, with or without the additional solvent. For example, the abrasive solutions may comprise 10% (volume percent or weight percent) abrasive and 90% deionized water, a ratio of 1:9 abrasives to solvent.

The material selective polishing step includes positioning the substrate in a carrier head for processing, providing the substrate to a third platen having a polishing article disposed therein, providing the material selective polishing composition to the platen, providing relative motion between the substrate and polishing article, and contacting the substrate and polishing article.

The material selective polishing composition is provided to the platen at a flow rate of between about 50 milliliters per minute (ml/min) and about 500 ml/min, such as between about 100 milliliters per minute (ml/min) and about 300 ml/min, for example, about 200 ml/min. Relative motion is provided between the substrate and the polishing article by providing a carrier head rotational rate and platen rotational rate between about 20 RPM and about 200 RPM, such as between about 50 RPM and about 120 RPM, for example 87 RPM for the carrier head rotational speed and about 93 RPM for platen rotational speed. The substrate and polishing pad are contacted at contact pressure between 1 psi and about 10 psi, such as between about 2 psi and about 8 psi, for example between about 3 psi and about 5 psi. The polishing process is performed for between about 30 and about 240 seconds, such as about 120 seconds. Processing parameters such as rotational speed, duration, and polishing pressure, will vary based upon the substrate material, material layer thicknesses, and compositions used and operator requirements. For example, if the high topography selective polishing step is performed on a single platen, the polishing time may be extended in order to remove the desired amount of material.

An example of the first high topography selective polishing step includes supplying a composition having a 1:9 ratio of DCM-P4 or Planerlite 6107 solution to deionized water at a composition delivery rate of about 200 ml/min and then removing residual polysilicon material from the substrate surface by polishing the substrate at a polishing pressure of about 3 psi with a platen rotational speed of about 93 rpm and a carrier head rotational speed of about 87 rpm for approximately 120 seconds.

A multi-step polishing process described herein was performed as follows on a substrate comprising a substrate material, such as silicon, a patterned silicon oxide layer of about 2800 Å disposed on the substrate material, and a polysilicon fill layer of about 2000 Å thick deposited on the patterned silicon oxide layer.

The substrate was positioned on a first polishing platen having a polishing article disposed thereon, supplying a composition of 1 part CES330-10 solution as the additive solution, 1 part ADD103-10 solution as the additive solution, and, 8 parts deionized water. The CES330-10 solution and the 1 part ADD103-10 solution have a 10% abrasive or additive to 90% deionized water composition, respectively, resulting in a composition having 1% abrasive (volume percent or weight percent), 1% additives (volume percent or weight percent), and the remainder deionized water, at a delivery rate of about 200 ml/min was supplied to the platen, contacting the polishing pad and substrate at a polishing pressure of about 3 psi with a platen rotational speed of about 93 rpm and a carrier head rotational speed of about 87 rpm for approximately 150 seconds to remove a first portion of polysilicon material.

The substrate was positioned on a second polishing platen having a polishing article supplying a composition of 1 part CES330-10 solution as the additive solution, 1 part ADD103-10 solution as the additive solution, and, 8 parts deionized water. The CES330-10 solution and the 1 part ADD103-10 solution have a 10% abrasive or additive to 90% deionized water composition, respectively, resulting in a composition having 1% abrasive (volume percent or weight percent), 1% additives (volume percent or weight percent), and the remainder deionized water, at a delivery rate of about 200 ml/min was supplied to the platen, contacting the polishing pad and substrate at a polishing pressure of about 3 psi with a platen rotational speed of about 93 rpm and a carrier head rotational speed of about 87 rpm for approximately 150 seconds to remove a second portion of polysilicon material. The substrate was observed to have minimal topographical deviation with a uniform planarized surface and minimal dishing.

The substrate was positioned on a third polishing platen having a polishing article disposed thereon, supplying a composition having a 1:9 ratio of DCM-P4 solution to deionized water at a composition delivery rate of about 200 ml/min to the platen, contacting the polishing pad and substrate at a polishing pressure of about 3 psi with a platen rotational speed of about 93 rpm and a carrier head rotational speed of about 87 rpm for approximately 120 seconds to remove residual polysilicon material. The substrate was observed to have minimal dishing of the polysilicon material and minimal erosion of the oxide material.

While the foregoing is directed to embodiments of the present invention, other and further embodiments of the invention may be devised without departing from the basic scope thereof, and the scope thereof is determined by the claims that follow.

What is claimed is:

1. A method for processing a substrate, comprising:
positioning the substrate in a polishing apparatus having one or more platens and polishing articles disposed on the one or more platens, and the substrate comprising a dielectric material and polysilicon material disposed thereon;
polishing the polysilicon material with a high topography selective polishing composition; and
polishing the polysilicon material with a material selective composition at a selectivity of polysilicon material to dielectric material between about 100:1 and about 1000:1.

2. The method of claim 1, wherein the dielectric material comprises silicon oxide.

3. The method of claim 1, wherein the polishing the polysilicon material with the high topography selective polishing composition is performed on a first platen and the polishing the polysilicon material with the material selective composition is performed on a second platen.

4. The method of claim 1, wherein a first portion of the polishing the polysilicon material with a high topography selective polishing composition is performed on a first platen, a second portion of the polishing the polysilicon material with the high topography selective polishing composition is performed on a second platen, and the polishing the polysilicon material with the material selective composition is performed on a third platen.

5. The method of claim 1, wherein the high topography selective composition comprises a ceria based abrasive composition.

6. The method of claim 1, wherein the high topography selective composition removed high topography features at a faster rate than low topography features.

7. The method of claim 1, wherein the material selective composition comprises a silica based abrasive composition.

8. The method of claim 7, wherein the silica based composition removes polysilicon material at a higher removal rate than the dielectric material.

9. A method for processing a substrate, comprising:
positioning a substrate comprising a polysilicon material disposed on a dielectric material in a polishing apparatus having one or more platens and polishing articles disposed on the one or more platens, and the polysilicon material comprises a non-planar surface topography having high topographical features and low topographical features;
planarizing the polysilicon material with a ceria based composition, wherein the ceria based composition removes high topographical features at a greater removal rate than low topographical features; and
polishing the polysilicon material with a silica based composition, wherein the silica based composition removes polysilicon material at a higher removal rate than the dielectric material, wherein the ratio of removal rates of the polysilicon material to the dielectric material between about 100:1 and about 1000:1.

10. The method of claim 9, wherein the dielectric material comprises silicon oxide.

11. The method of claim 9, wherein the removing the surface topography is performed on a first platen and the polishing the polysilicon material is performed on a second platen.

12. The method of claim 9, wherein a first portion of the removing the surface topography is performed on a first platen, a second portion of the removing the surface topography is performed on a second platen, and the polishing the polysilicon material is performed on a third platen.

13. The method of claim 9, wherein the difference between the high topography features and the low topography features is between about 500 Å and about 5000 Å.

14. A method for processing a substrate, comprising:
positioning the substrate in a polishing apparatus having one or more platens and polishing articles disposed on the one or more platens, and the substrate comprising an oxide based material and polysilicon material having a non-planar surface topography disposed thereon;
polishing the substrate to remove a first portion of the polysilicon non-planar surface topography with a first high topography selective composition;
polishing the substrate to remove a second portion of the polysilicon non-planar surface topography with a second high topography selective composition; and
polishing the polysilicon material with a silica based composition to expose the oxide based material at a selectivity of polysilicon material to oxide based material between about 100:1 and about 1000:1.

15. The method of claim 14, wherein the polishing the substrate to remove the first portion of the polysilicon non-planar surface topography is performed on a first platen, a second portion of the polysilicon non-planar surface topography is performed on a second platen, and the polishing the polysilicon material with a silica based composition is performed on a third platen.

16. The method of claim 14, wherein the high topography selective composition comprises a ceria based abrasive composition.

17. The method of claim 14, wherein the silica based composition removes polysilicon material at a higher removal rate than the dielectric material.
